(19) United States
(12) Patent Application Publication
(10) Pub. No.: US 2025/0311210 A1
(43) Pub. Date: Oct. 2, 2025

(54) FLASH MEMORY DEVICE AND METHOD FOR FABRICATING SAME

(71) Applicant: Hangzhou HFC Semiconductor Co., Hangzhou (CN)

(72) Inventors: Xingyuan WANG, Hangzhou (CN); Liang LI, SINGAPORE (SG); Li JI, Hangzhou (CN); Mingyu HU, Hangzhou (CN); Weixing LI, Hangzhou (CN); Yang ZHANG, Hangzhou (CN); Jian ZHANG, Hangzhou (CN)

(21) Appl. No.: 18/649,493

(22) Filed: Apr. 29, 2024

(30) Foreign Application Priority Data
Mar. 27, 2024 (CN) 202410358527.5

(51) Int. Cl. H10B 41/30; H01L 21/3213; H01L 21/768; H10B 41/10; H10B 41/43

(52) U.S. Cl. CPC H10B 41/30; H01L 21/32139; H01L 21/76816; H10B 41/10; H10B 41/43

(57) ABSTRACT

A flash memory device and a method for fabricating the device are disclosed. The method includes: providing a semiconductor substrate comprising an array region and a peripheral region, multiple first gate structures formed on the semiconductor substrate in the array region, a second gate structure formed on the semiconductor substrate in the peripheral region, adjacent first gate structures spaced by a first gap or a second gap, the first gap having a width smaller than a width of the second gap; forming a first dielectric layer over the semiconductor substrate; forming a second dielectric layer over the first dielectric layer; forming a hard mask layer over the second dielectric layer; forming spacers on opposite sides of the second gate structure by etching the hard mask layer; forming a patterned photoresist layer that covers the spacers; and removing a remaining portion of the hard mask layer and the patterned photoresist layer.

### CROSS-REFERENCE TO RELATED APPLICATION

This application claims the priority of Chinese patent application number 202410358527.5, filed on Mar. 27, 2024 and entitled “FLASH MEMORY DEVICE AND METHOD FOR FABRICATING SAME”, the entire contents of which are incorporated herein by reference.

### TECHNICAL FIELD

The present invention relates to the field of semiconductor technology and, in particular, to a flash memory device and a method for fabricating the device.

### BACKGROUND

Flash memory devices are non-volatile memory devices widely used in personal computers and electronics, thanks to their advantages of allowing repeated write, read and erase and other data operations and retaining stored data even after power is removed.

There are two types of flash memory: NOR (parallel-connected arrangement of memory cells between a bit line and ground) and NAND (series-connected arrangement of memory cells between a bit line and ground). As the parallel-connected arrangement enables high-speed random access during read operations, NOR flash memory has been widely used in mobile phone booting.

Conventional methods available for fabrication of NOR flash memory devices suffer from problems including difficult process control and hard mask residuals.

### SUMMARY OF THE INVENTION

It is an object of the present invention to provide a flash memory device and a method for fabricating the device, which overcome the problems associated with conventional methods available for fabrication of NOR flash memory devices, including difficult process control and hard mask residuals.

To this end, the present invention provides a method for fabricating a flash memory device, which comprises:
providing a semiconductor substrate comprising an array region and a peripheral region, wherein a plurality of first gate structures are formed on the semiconductor substrate in the array region, wherein a second gate structure is formed on the semiconductor substrate in the peripheral region, wherein adjacent first gate structures are spaced by a first gap or a second gap, the first gap having a width smaller than a width of the second gap, and wherein forming a first dielectric layer over the semiconductor substrate, which covers the plurality of first gate structures, the second gate structure and the semiconductor substrate;
forming, over the first dielectric layer, a second dielectric layer filling up the first gap;
forming, over the second dielectric layer, a hard mask layer filling up the second gap;
forming spacers on opposite sides of the second gate structure by etching the hard mask layer;
forming a patterned photoresist layer which covers the spacers; and
removing a remaining portion of the hard mask layer and the patterned photoresist layer.

The present invention also provides a flash memory device comprising:
a semiconductor substrate comprising an array region and a peripheral region;
a plurality of first gate structures located on the semiconductor substrate in the array region, adjacent first gate structures spaced by a first gap or a second gap, the first gap having a width smaller than a width of the second gap;
a second gate structure located on the semiconductor substrate in the peripheral region;
a first dielectric layer covering the plurality of first gate structures, the second gate structure and the semiconductor substrate; and
a second dielectric layer covering the first dielectric layer and filling up the first gap.

In the flash memory device and method of the present invention, the narrower first gap remains filled up by the dielectric layer, thereby preventing subsequent hard mask or photoresist residuals in the first gap. This allows easier process control, enhanced process reliability and improved quality and reliability of the resulting flash memory device. Moreover, since the first gap is filled up with the dielectric layer, in addition to subsequent hard mask or photoresist residuals, metal residuals can also be prevented from being left in the first gap from the salicide process. As a result, a simple layer can be formed in the first gap, which allows easier process control and enhanced process reliability. In particular, after the salicide is exposed as a result of an etching process, more accurate process control can be achieved, and over-etching or under-etching can be effectively avoided, resulting in more reliable connections between the plugs and the salicide.

### BRIEF DESCRIPTION OF THE DRAWINGS

FIGS. 1 to 10 show schematic cross-sectional views of intermediate device structures resulting from process steps in a method for fabricating a flash memory device according to embodiments of the present application.

FIG. 11 shows a schematic top view of source and drain regions on opposite sides of a first gate structure according to an embodiment of the present application.

FIG. 12 schematically illustrates hard mask residuals according to the prior art.

In these figures, 100, a semiconductor substrate; 101, an array region; 102, a peripheral region; 110, 110A, 110B, 110C, first gate structures; 111, a tunnel oxide layer; 112, a floating gate structure; 113, an ONO structure; 114, a control gate structure; 120, a second gate structure; 121, a gate dielectric layer; 122, a gate; 130, a first dielectric layer; 140, a second dielectric layer; 150, a hard mask layer; 160, spacers; 170, a patterned photoresist layer; 180, a metal layer; 190, first gate salicide; 200, second gate salicide; 210, source salicide and drain salicide; 220, a third dielectric layer; 230, a fourth dielectric layer; 240, first openings; 250, a second opening; 260, third openings; 270, first plugs; 280, a second plug; 290, third plugs;
S1, a first gap; S2, a second gap; H1, H2, widths; D1, hard mask residuals.

### DETAILED DESCRIPTION

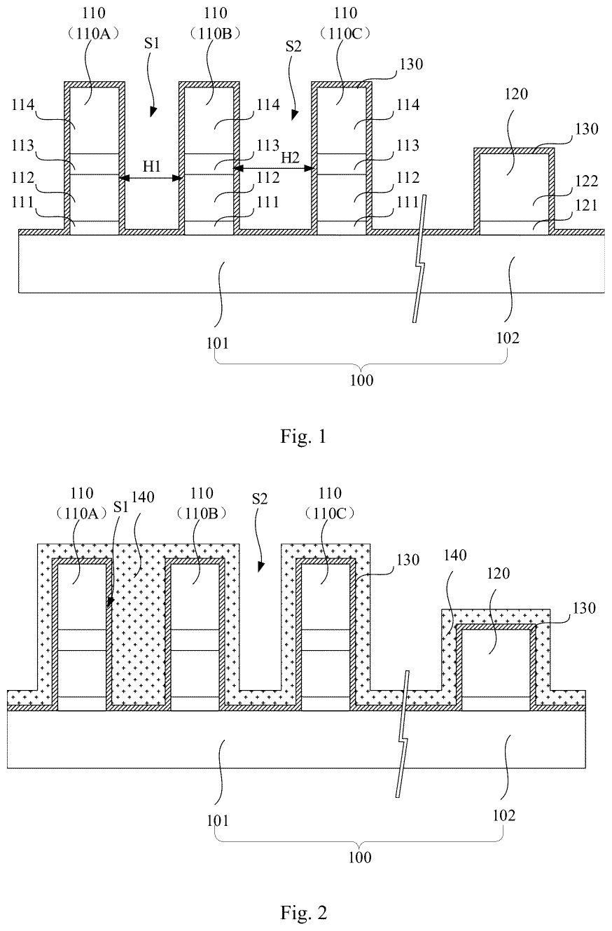

Reference is made to FIGS. 1 to 10, which show schematic cross-sectional views of intermediate device structures resulting from process steps in a method for fabricating a flash memory device according to embodiments of the present application.

As shown in FIG. 1, a semiconductor substrate 100 is provided, which may be a silicon, germanium, silicon germanium, silicon carbide, gallium arsenide or other substrate. The semiconductor substrate 100 includes an array region 101 and a peripheral region 102. According to embodiments of the present application, a plurality of first gate structures 110 are formed on the semiconductor substrate 100 in the array region 101, and a second gate structure 120 is formed on the semiconductor substrate 100 in the peripheral region 102. A source region and drain region (not shown) are formed in the semiconductor substrate 100 on opposite sides of each of the first gate structures 110 and the second gate structure 120.

With continued reference to FIG. 1, each first gate structure 110 includes a tunnel oxide layer 111, a floating gate structure 112, an oxide-nitride-oxide (ONO) structure 113 and a control gate structure 114, which are stacked together. The second gate structure 120 includes a gate dielectric layer 121 and a gate 122, which are stacked together.

Adjacent first gate structures 110 are spaced by a first gap S1 or a second gap S2. A width H1 of the first gap S1 is smaller than a width H2 of the second gap S2. FIG. 1 schematically shows three of the first gate structures 110, namely, a first gate structure 110A, a first gate structure 110B and a first gate structure 110C. The first gate structure 110B and the first gate structure 110A are spaced by a first gap S1, and the first gate structure 110B and the first gate structure 110C are spaced by a second gap S2.

With continued reference to FIG. 1, a first dielectric layer 130 is formed over the semiconductor substrate 100, which covers the first gate structures 110, the second gate structure 120 and the semiconductor substrate 100. According to embodiments of the present application, the first dielectric layer 130 is an oxide layer, which may be formed by a thermal oxidation process.

Subsequently, as shown in FIG. 2, a second dielectric layer 140 is formed on the first dielectric layer 130. Since the width H1 of the first gap S1 is smaller than the width H2 of the second gap S2, the first gap S1 is filled up by the second dielectric layer 140, while the second gap S2 is only partially filled by the second dielectric layer 140. According to embodiments of the present application, the second dielectric layer 140 is formed by a deposition process. The second dielectric layer 140 is preferred to be silicon nitride and have a thickness of 300 Å to 450 Å.

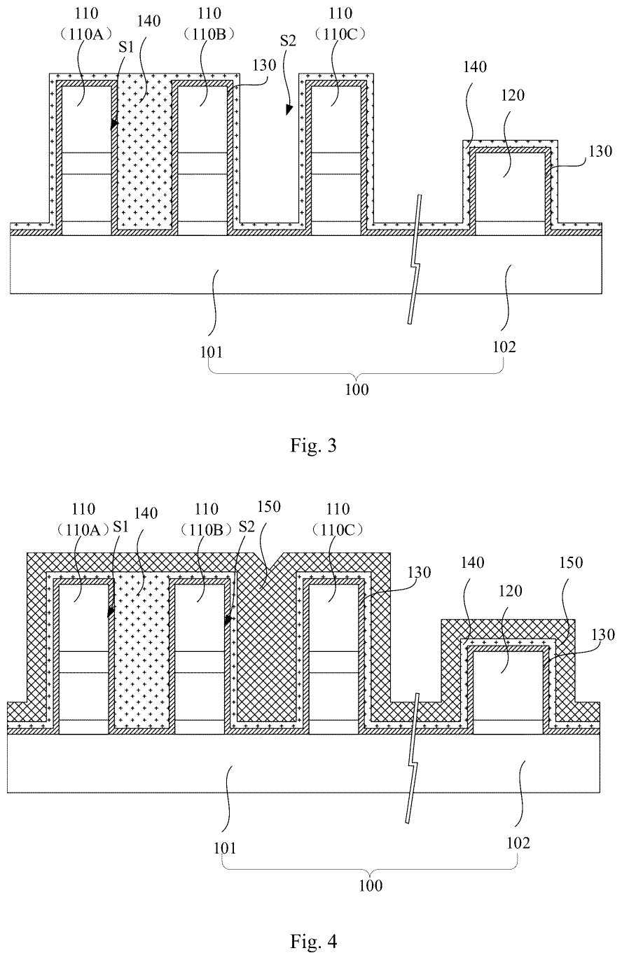

Next, as shown in FIG. 3, an etching process is performed to reduce the thickness of the second dielectric layer 140. Since the width H1 of the first gap S1 is smaller than the width H2 of the second gap S2, as a result of the etching process, the second dielectric layer 140 in the second gap S2 is thinned, while the first gap S1 remains filled with the second dielectric layer 140. Specifically, a wet etching process may be carried out to reduce the thickness of the second dielectric layer 140. Optionally, the thickness of the dielectric layer 140 is reduced by 100 Å to 220 Å.

Referring to FIG. 4, a hard mask layer 150 is then formed on the second dielectric layer 140. The hard mask layer 150 may be formed by a deposition process. Optionally, the hard mask layer 150 has a thickness of 1000 Å to 2000 Å and fills up the second gap S2.

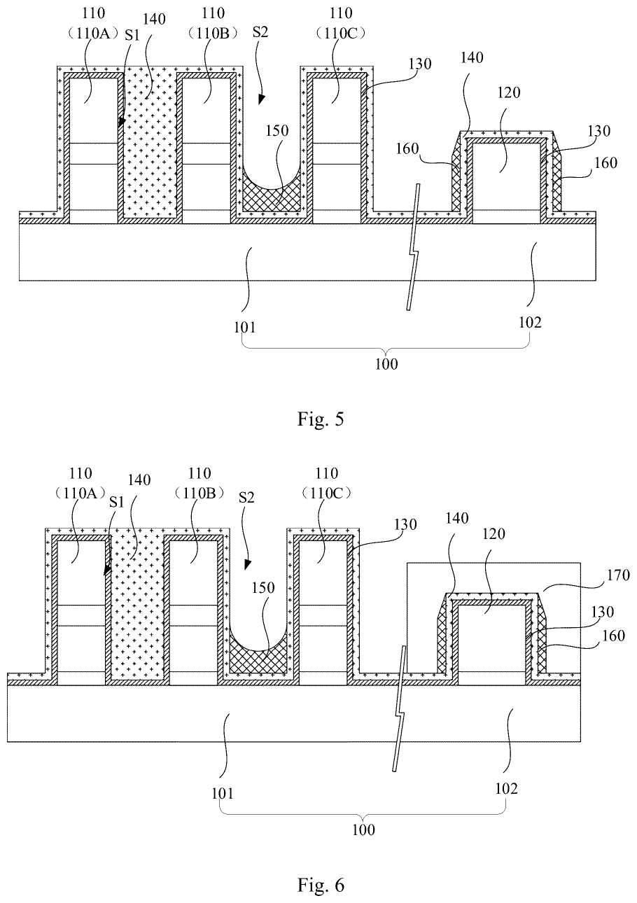

As shown in FIG. 5, an etching process is then performed on the hard mask layer 150 to form spacers 160 on opposite sides of the second gate structure 120. During the etching process on the hard mask layer 150 for forming the spacers 160, the hard mask layer 150 in the second gap S2 may be entirely or partially removed. According to embodiments of the present application, in order to ensure satisfactory quality of the resulting spacers 160 and to prevent the spacers 160 from being over-etched, the hard mask layer 150 is partially retained in the second gap S2.

As shown in FIG. 6, a patterned photoresist layer 170 is formed, which covers the spacers 160. Optionally, the patterned photoresist layer 170 may further cover the second gate structure 120.

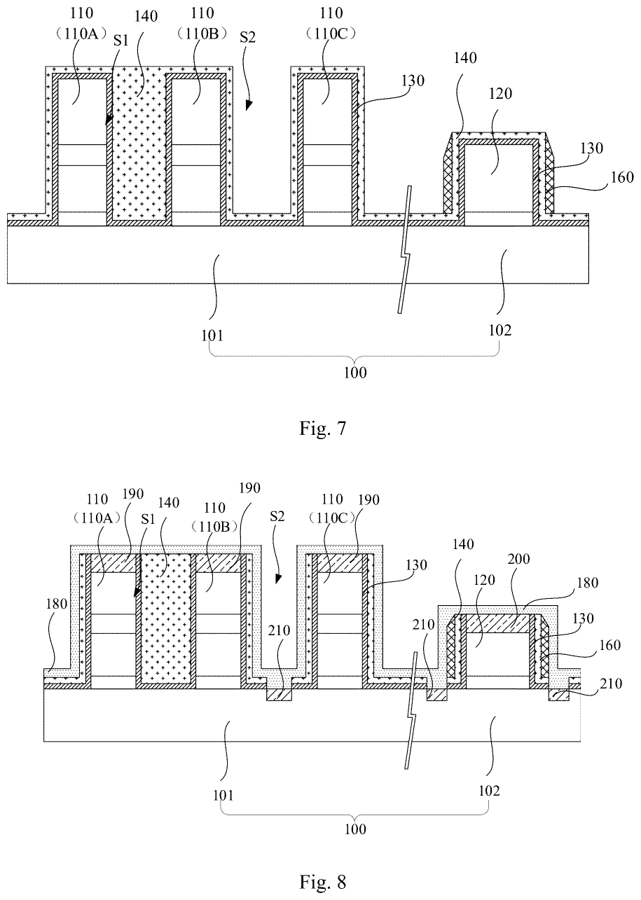

Afterwards, as shown in FIG. 7, the hard mask layer 150 in the second gap S2, i.e., the remaining hard mask layer 150, as well as the patterned photoresist layer 170, is removed. Since the second gap S2 is relatively wide, the hard mask layer 150 can be removed in a convenient and effective manner. At the same time, since the first gap S1 is filled up by the second dielectric layer 140, the hard mask layer 150 will not be filled therein. Thus, the problem of hard mask residuals D1, as shown in FIG. 12, can be overcome. According to conventional methods, the hard mask layer is filled in all the gaps, and during the removal of the remaining hard mask layer from the gaps, only the hard mask layer in wide gaps can be completely removed, but is difficult to completely remove the hard mask layer from narrow gaps, thus leaving hard mask residuals D1 therein. Specifically, the remaining hard mask layer 150 may be removed using an etching process, and the patterned photoresist layer 170 may be removed using a strip-off process.

Referring to FIG. 8, according to embodiments of the present application, a process is carried out to expose the first gate structures 110, the second gate structure 120 and the source and drain regions on opposite sides of each of the first gate structures 110 and the second gate structure 120. Specifically, the process may be an etching process, or a combined polishing and etching process.

After that, a metal layer 180 is formed, which covers exposed surfaces of the resulting structure, including the exposed surfaces of the first gate structures 110, the second gate structure 120, the source and drain regions on opposite sides of each of the first gate structures 110 and the second gate structure 120, the first dielectric layer 130, the second dielectric layer 140 and the spacers 160. The metal layer 180 then reacts with the surface of each first gate structure 110 to form first gate salicide 190, reacts with the surface of the second gate structure 120 to form second gate salicide 200 and reacts with the surfaces of the source and drain regions on opposite sides of each of the first gate structure 110 and the second gate structure 120 to form a source salicide and a drain salicide 210.

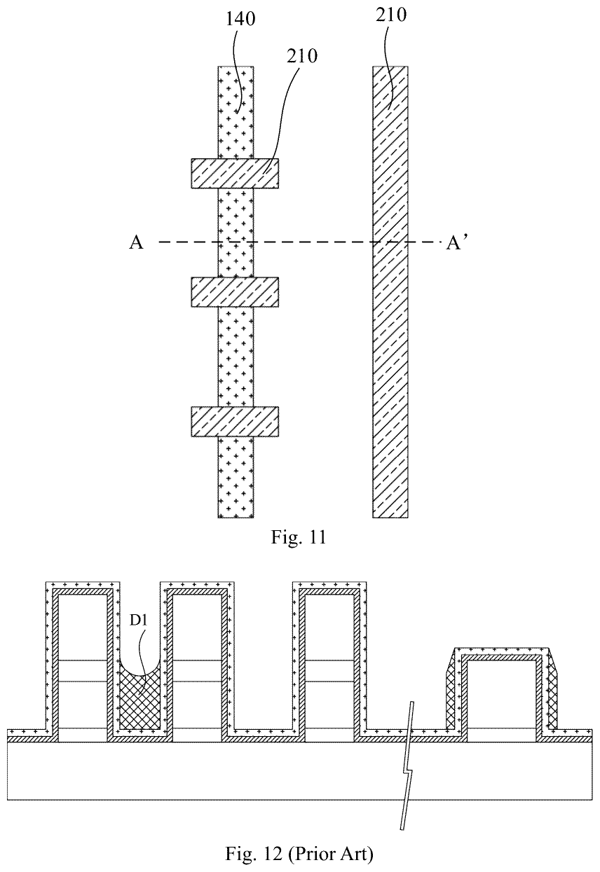

Combined reference is made to FIG. 11, which shows a schematic top view of source and drain regions on opposite sides of the first gate structure 110 (more precisely, the first gate structure 110B) according to embodiments of the present application. The schematic cross-sectional view of FIG. 8 is taken along AA′ of FIG. 11. As shown in FIGS. 8 and 11, according to embodiments of the present application, the surface of the drain region on one side of the first gate structure 110 (the right side as viewed in the orientation of FIG. 11) is entirely covered by the source salicide and drain salicide 210, while the surface of the source region on the other side of the first gate structure 110 (the left side as viewed in the orientation of FIG. 11) is partially covered by the source salicide and drain salicide 210. The rest portion of the surface of the source region on the other side of the first gate structure 110 is covered by the second dielectric layer 140.

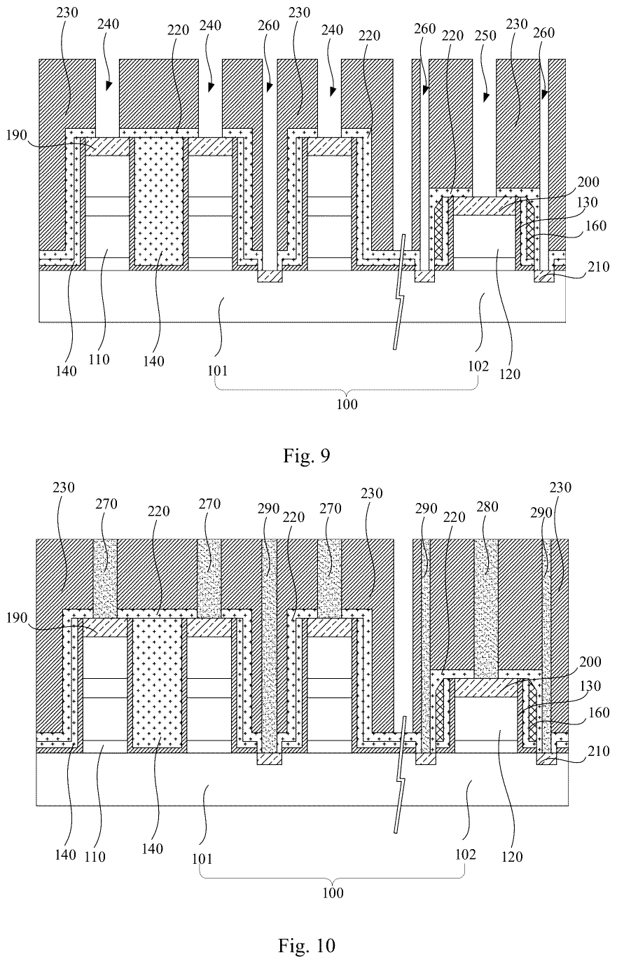

Referring to FIG. 9, the unreacted portion of the metal layer 180 is removed, and a third dielectric layer 220 is then formed, which covers exposed surfaces of the resulting structure, including the first gate salicide 190, the second gate salicide 200, the source salicide and drain salicide 210, the first dielectric layer 130, the second dielectric layer 140 and the spacers 160. According to embodiments of the present application, the third dielectric layer 220 is silicon nitride. Subsequently, a fourth dielectric layer 230 is formed, which covers the third dielectric layer 220. Optionally, the fourth dielectric layer 230 is silicon oxide.

Additionally, the fourth dielectric layer 230 and the third dielectric layer 220 are etched, forming first openings 240 exposing the first gate salicide 190, a second opening 250 exposing the second gate salicide 200 and third openings 260 exposing the source salicide and drain salicide 210.

After that, as shown in FIG. 10, first plugs 270 connected to the first gate structures 110 are formed in the first openings 240, a second plug 280 connected to the second gate structure 120 in the second opening 250, and third plugs 290 connected to the source and drain regions in the third openings 260. More precisely, the first plugs 270 are connected to the first gate salicide 190, the second plug 280 to the second gate salicide 200, and the third plugs 290 to the source salicide and drain salicide 210.

In embodiments of the present application, there is also provided a flash memory device comprising: a semiconductor substrate 100 comprising an array region 101 and a peripheral region 102; a plurality of first gate structures 110 located on the semiconductor substrate 100 in the array region 101, adjacent first gate structures 110 spaced by a first gap S1 or a second gap S2, the first gap S1 having a width smaller than a width of the second gap S2; a second gate structure 120 located on the semiconductor substrate 100 in the peripheral region 102; a first dielectric layer 130 covering the first gate structures 110, the second gate structure 120 and the semiconductor substrate 100; and a second dielectric layer 140 covering the first dielectric layer 130 and filling up the first gap S1.

Additionally, source and drain regions (not shown) are formed in the semiconductor substrate 100 on opposite sides of each of the first gate structure 110 and the second gate structure 120. First gate salicide 190 is formed on the first gate structures 110, second gate salicide 220 on the second gate structure 120, and source salicide and drain salicide 210 on the source and drain regions.

According to embodiments of the present application, the flash memory device further includes: a third dielectric layer 220 covering the second dielectric layer 140; a fourth dielectric layer 230 covering the third dielectric layer 220; first plugs 270 extending through the fourth dielectric layer 230 and the third dielectric layer 220, and connected to the first gate structures 110; a second plug 280 extending through the fourth dielectric layer 230 and the third dielectric layer 220, and connected to the second gate structure 120; and third plugs 290 extending through the fourth dielectric layer 230 and the third dielectric layer 220, and connected to the source region and drain region.

According to embodiments of the present application, the flash memory device is fabricated according to a method, in which the narrower first gap is filled up by the dielectric layer, thereby preventing subsequent hard mask or photoresist residuals in the first gap. This allows easier process control, enhanced process reliability and improved quality and reliability of the resulting flash memory device.

Furthermore, since the first gap is filled up with the dielectric layer, in addition to subsequent hard mask or photoresist residuals, metal residuals can also be prevented from being left in the first gap from a salicide process. As a result, a simple layer can be formed in the first gap, which allows easier process control and enhanced process reliability. In particular, after the salicide is exposed as a result of an etching process, more accurate process control can be achieved, and over-etching or under-etching can be effectively avoided, resulting in more reliable connections between the plugs and the salicide.

The description presented above is merely that of some embodiments of the present invention and is not intended to limit the scope thereof in any sense. Any and all changes and modifications made by those of ordinary skill in the art based on the above teachings fall within the scope of the invention.

1. A method for fabricating a flash memory device, comprising:
providing a semiconductor substrate comprising an array region and a peripheral region, wherein a plurality of first gate structures are formed on the semiconductor substrate in the array region, wherein a second gate structure is formed on the semiconductor substrate in the peripheral region, wherein adjacent first gate structures are spaced by a first gap or a second gap, the first gap having a width smaller than a width of the second gap;
forming a first dielectric layer over the semiconductor substrate, wherein the first dielectric layer covers the plurality of first gate structures, the second gate structure and the semiconductor substrate;
forming a second dielectric layer over the first dielectric layer, wherein the second dielectric layer fills up the first gap;
forming a hard mask layer over the second dielectric layer, wherein the hard mask layer fills up the second gap;
forming spacers on opposite sides of the second gate structure by etching the hard mask layer;
forming a patterned photoresist layer that covers the spacers; and
removing a remaining portion of the hard mask layer and the patterned photoresist layer.

2. The method of claim 1, wherein forming the second dielectric layer filling up the first gap over the first dielectric layer comprises:
forming the second dielectric layer over the first dielectric layer to a thickness of 300 Å to 450 Å; and
etching the second dielectric layer to thin the second dielectric layer by a thickness of 100 Å to 220 Å.

3. The method of claim 1, wherein the first dielectric layer is silicon oxide, and the second dielectric layer is silicon nitride.

4. The method of claim 1, wherein the hard mask layer that is formed over the second dielectric layer and fills up the second gap has a thickness of 1000 Å to 2000 Å.

5. The method of claim 1, wherein removing the remaining portion of the hard mask layer and the patterned photoresist layer comprises:
etching away the remaining portion of the hard mask layer; and
stripping off the patterned photoresist layer.

6. The method of claim 1, wherein forming a source region and a drain region in the semiconductor substrate on opposite sides of each of the first gate structure and the second gate structure, and
wherein the method further comprises, after removing the remaining portion of the hard mask layer and the patterned photoresist layer:
etching the second and first dielectric layers to expose the plurality of first gate structures, the second gate structure and the source and drain regions on opposite sides of each of the first gate structure and the second gate structure;
forming a metal layer over the plurality of first gate structures, the second gate structure and the source and drain regions, wherein the metal layer reacts with a surface of each first gate structure to form a first gate salicide, reacts with a surface of the second gate structure to form a second gate salicide and reacts with surfaces of the source and drain regions to form a source salicide and a drain salicide; and
removing an unreacted portion of the metal layer.

7. The method of claim 6, further comprising, after removing the unreacted portion of the metal layer:
forming a third dielectric layer covering the first gate salicide, the second gate salicide, the source and drain salicides, the first dielectric layer, the second dielectric layer and the spacers;
forming a fourth dielectric layer covering the third dielectric layer;
etching the fourth and third dielectric layers to form first openings exposing the first gate salicide, a second opening exposing the second gate salicide and third openings exposing the source and drain salicides; and
forming first plugs connected to the first gate structures in the first openings, a second plug connected to the second gate structure in the second opening and third plugs connected to the source and drain regions in the third openings.

8. The method of claim 7, wherein the third dielectric layer is silicon nitride, and the fourth dielectric layer is silicon oxide.

9. A flash memory device, comprising:
a semiconductor substrate comprising an array region and a peripheral region;
a plurality of first gate structures located on the semiconductor substrate in the array region, wherein adjacent first gate structures are spaced by a first gap or a second gap, and wherein the first gap has a width smaller than a width of the second gap;
a second gate structure located on the semiconductor substrate in the peripheral region;
a first dielectric layer covering the plurality of first gate structures, the second gate structure and the semiconductor substrate; and
a second dielectric layer covering the first dielectric layer and filling up the first gap.

10. The flash memory device of claim 9, wherein a source region and a drain region are formed in the semiconductor substrate on opposite sides of each of the first gate structure and the second gate structure, and wherein a first gate salicide is formed on a surface of the first gate structure, a second gate salicide formed on a surface of the second gate structure and a source salicide and a drain salicide formed on surfaces of the source and drain regions.

11. The flash memory device of claim 9, wherein the first dielectric layer is silicon oxide, and the second dielectric layer is silicon nitride.
